(19) United States
(12) Patent Application Publication
(10) Pub. No.: US 2018/0190681 A1
(43) Pub. Date: Jul. 5, 2018

(54) ARRAY SUBSTRATE, METHOD FOR MANUFACTURING THE SAME, AND DISPLAY PANEL AND DISPLAY DEVICE COMPRISING THE SAME

(71) Applicant: BOE TECHNOLOGY GROUP CO., LTD., Beijing (CN)

(72) Inventors: Jiushi WANG, Beijing (CN); Zhanfeng CAO, Beijing (CN); Qi YAO, Beijing (CN); Jing FENG, Beijing (CN)

(73) Assignee: BOE TECHNOLOGY GROUP CO., LTD., Beijing (CN)

(21) Appl. No.: 15/690,029

(22) Filed: Aug. 29, 2017

(30) Foreign Application Priority Data
Jan. 4, 2017 (CN) 201710005666.X

(51) Int. Cl. H01L 27/12

(52) U.S. Cl. CPC H01L 27/1244; H01L 27/127; H01L 27/1225

(57) ABSTRACT

The present disclosure provides an array substrate and a method for manufacturing the same and a display panel and a display device comprising the same. The method for manufacturing the array substrate provided in the present disclosure comprises: forming a first metal layer; forming an uneven structure on a surface of the first metal layer; providing a photoresist on the surface of the first metal layer where the uneven structure has been formed; and exposing and developing the photoresist and etching the first metal layer so as to form a first metal pattern.

### CROSS-REFERENCE TO RELATED APPLICATION

This application claims priority to Chinese Patent Application No. 201710005666.X filed on Jan. 4, 2017, which is incorporated herein by reference in its entirety.

### TECHNICAL FIELD

The present disclosure relates to the field of display technology, and in particular to an array substrate, a method for manufacturing the same, and a display panel and a display device comprising the array substrate.

### BACKGROUND

To improve display quality of a thin film transistor (TFT) panel, further refinement of the TFT panel and more pixels per inch (PPI) are required. Thus, original aluminum wiring is replaced by copper wiring. In copper wiring, a desired pattern is usually formed by a wet-etching process. An etching solution for the wet-etching process contains water in an amount exceeding 80%, which tends to cause a photoresist layer to peel off from the surface of the copper thin film during the wet-etching process. Consequently, the desired pattern cannot be obtained successfully, and the manufacturing of the array substrate fails.

### SUMMARY

The present disclosure provides in at least one embodiment an array substrate and its manufacturing method, so as to prevent the photoresist from peeling off from the surface of the metal layer in the process of etching the metal layer and improves yield of the array substrates.

Further, the present disclosure provides in at least one embodiment a display panel and a display device containing the array substrate, which exhibit high display quality.

In an aspect, the present disclosure provides a method for manufacturing an array substrate, comprising:

forming a first metal layer;

forming an uneven structure on a surface of the first metal layer;

providing a photoresist on the surface of the first metal layer where the uneven structure has been formed; and

exposing and developing the photoresist and etching the first metal layer so as to form a layer of a first metal pattern.

Optionally, the first metal layer is a source-drain metal layer, and the first metal pattern comprises a source-drain electrode pattern.

Optionally, prior to forming the first metal layer, the method further comprises:

forming a gate electrode on a base substrate;

forming a gate insulating layer on the gate electrode; and

forming an active semiconductor layer on the gate insulating layer, wherein the first metal layer is formed on the active semiconductor layer.

Optionally, the uneven structure on the surface of the first metal layer is formed by subjecting the surface of the first metal layer to plasma treatment.

Optionally, the plasma treatment on the surface of the first metal layer is performed by using a halogen-containing gas.

Optionally, the first metal layer is made of copper.

Optionally, the halogen-containing gas is a gas containing one or more of Cl₂, Br₂, I₂, HCl, HBr and HI.

Optionally, the plasma treatment on the surface of the first metal layer is performed at a temperature lower than 200 degrees Celsius.

Optionally, the etching is a wet-etching process.

In another aspect, the present disclosure provides an array substrate comprising a base substrate, a gate electrode, a gate insulating layer, an active semiconductor layer and a layer of a first metal pattern, wherein an uneven structure is formed on a surface of the layer of the first metal pattern.

Optionally, the uneven structure is a granular structure.

Optionally, the uneven structure on the surface of the first metal layer is made of a metal halide.

Optionally, the first metal pattern comprises a source electrode pattern, a drain electrode or a source-drain electrode pattern.

In a still another aspect, the present disclosure provides a display panel comprising the array substrate as described above.

In a still another aspect, the present disclosure provides a display device comprising the display panel as described above.

The technical solutions provided in at least one embodiment according to the present disclosure produce the following advantageous effect. By forming the uneven structure on the surface of the first metal layer and then providing the photoresist on the surface of the first metal layer where the uneven structure has been formed, adhesion of the first metal layer to the photoresist adhered to its surface is increased, thus preventing the peeling off of the photoresist during the exposure and development of the photoresist and etching of the first metal layer to form the source electrode and the drain electrode. As a result, the manufacturing can go smoothly and the yield of the array substrates can be improved.

### BRIEF DESCRIPTION OF THE DRAWINGS

In order to illustrate the technical solutions of the embodiments of the present disclosure in a clearer manner, the accompanying drawings desired for the present disclosure will be described briefly hereinafter. Obviously, the following drawings merely relate to some embodiments of the present disclosure, and based on these drawings, a person skilled in the art may obtain other drawings without any creative effort.

FIG. 1 is a flow chart showing a method for manufacturing an array substrate of an embodiment of the present disclosure.

FIGS. 2(a) to 2(g) are structural schematic views of the substrate obtained in each step of the method for manufacturing the array substrate of the embodiment of the present disclosure: (a) a structure on which a gate electrode is formed; (b) a structure on which the gate electrode and a gate insulating layer are formed; (c) a structure on which the gate electrode, the gate insulating layer and an active semiconductor layer are formed; (d) a structure on which the gate electrode, the gate insulating layer, the active semiconductor layer and a source-drain metal layer are formed; (e) a structure on which the source-drain metal layer having an uneven surface is formed after plasma treatment; (f) a structure on which the gate electrode, the gate insulating layer, the active semiconductor layer, the source-drain metal layer and a photoresist are formed; (g) a structure formed after the structure obtained in (f) is subjected to a wet-etching process.

### DETAILED DESCRIPTION

The present disclosure provides in at least one embodiment an array substrate and its manufacturing method, so as to prevent the photoresist from peeling off from the surface of the metal layer in the process of etching the metal layer and thus improves yield of the array substrates. Further, the present disclosure provides in at least one embodiment a display panel and a display device containing the array substrate, which exhibit high display quality.

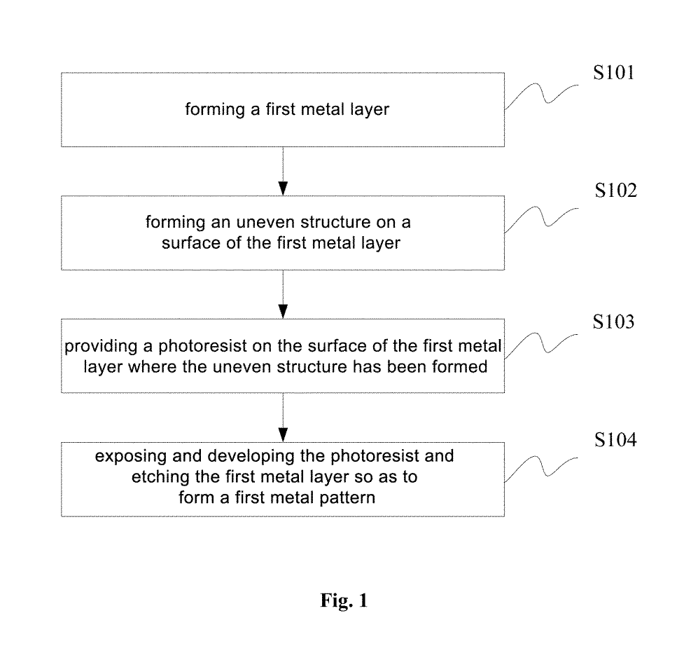

Referring to FIG. 1, the present disclosure provides in an embodiment a method for manufacturing an array substrate, comprising:

S101: forming a first metal layer;

S102: forming an uneven structure on a surface of the first metal layer;

S103: providing a photoresist on the surface of the metal layer where the uneven structure has been formed; and

S104: exposing and developing the photoresist and etching the first metal layer so as to form a first metal pattern.

In the method for manufacturing the array substrate provided in the embodiment of the present disclosure, by forming the uneven structure on the surface of the first metal layer and then providing the photoresist on the surface of the first metal layer where the uneven structure has been formed, adhesion of the first metal layer to the photoresist adhered to its surface is increased, thus preventing the peeling off of the photoresist during the exposure and development of the photoresist and etching of the first metal layer to form the source electrode and the drain electrode. As a result, the manufacturing can go smoothly and the yield of the array substrates can be improved.

Optionally, the first metal layer is a source-drain metal layer and the first metal pattern includes the source-drain electrode pattern.

In addition to the source-drain metal layer, the first metal layer may be a gate metal layer, and the first metal layer may be used for forming patterns of a gate electrode and a gate line. The embodiment of the present disclosure will be explained hereinafter by taking the source-drain metal layer as an example, and the embodiments of the present disclosure will not be limited thereto.

Optionally, prior to forming the first metal layer, the method further includes: forming a gate electrode on a base substrate; forming a gate insulating layer on the gate electrode; and forming an active semiconductor layer on the gate insulating layer, wherein the first metal layer is formed on the active semiconductor layer.

Optionally, the uneven structure is a granular structure. The uneven structure may be a structure having any other shapes. The effect of improving the adhesion of the photoresist can be achieved so long as the surface of the source-drain metal layer is not smooth or has surface roughness Ra which is at least 30 micrometers, preferably at least 100 micrometers. Therefore, the granular structure may further increase the adhesion of the source-drain metal layer to the photoresist adhered to its surface.

Optionally, the source-drain metal layer is subjected to plasma treatment so as to form an uneven granular structure on the surface of the source-drain metal layer.

Optionally, the plasma treatment on the source-drain metal layer is performed by using a halogen-containing gas.

Optionally, the source-drain electrode metal layer is made of copper.

Optionally, the granular structure is a solid copper chloride (CuClₓ) structure.

Optionally, the halogen-containing gas is a gas containing one or more of chlorine (Cl₂), bromine (Br₂), iodine (I₂), hydrogen chloride (HCl), hydrogen bromide (HBr) and hydrogen iodide (HI).

Since copper halide will become gas at a temperature of more than 200 degrees Celsius, the plasma treatment on copper using the halogen-containing gas should be performed at a temperature not more than 200 degrees Celsius. Therefore, when copper is used for forming the source-drain metal layer, the plasma treatment on the source-drain metal layer should be performed at a temperature lower than 200 degrees Celsius.

Optionally, the etching is a wet-etching process.

Optionally, the gate electrode includes one or any combination of copper (Cu), titanium (Ti), molybdenum (Mo), aluminum (Al), tungsten (W) and chromium (Cr).

Optionally, the gate insulating layer includes one or any combination of TiO₂, Yi₂O₃, Al₂O₃, SiNₓ, SiON and SiO₂.

Optionally, the active semiconductor layer is made of amorphous silicon (a-Si), or the active semiconductor layer is made of an oxide semiconductor. Optionally, the oxide semiconductor is one or more selected from the group consisting of indium gallium zinc oxide (InGaZnO, IGZO), indium zinc oxide (IZO), indium gallium oxide (IGO), gallium zinc oxide (GZO) and zinc oxide (ZnO), indium tin zinc oxide (ITZO).

In another aspect, the present disclosure provides an array substrate which is manufactured using the method as provided in the above embodiment of the present disclosure, which array substrate comprises an array substrate, a gate electrode, a gate insulating layer, an active semiconductor layer and a layer of a first metal pattern, wherein an uneven structure is formed on a surface of the layer of the first metal pattern.

Optionally, in the array substrate, the gate electrode is located on the substrate; the gate insulating layer is located on the gate electrode, and the active semiconductor layer is located on the gate insulating layer.

Optionally, the layer of the first metal pattern is a source-drain metal layer, and the first metal pattern includes a source-drain electrode pattern.

In a still another aspect, the present disclosure further provides a display panel including the array substrate as described above.

In a still further aspect, the present disclosure further provides a display device including the display panel as described above.

Taking copper as the material of the source electrode and the drain electrode for example, the present disclosure provides in at least one embodiment a method for improving the adhesion of a photoresist to the surface of metal copper, which mainly comprises: forming a gate electrode, a gate insulating layer and an active semiconductor layer on a base substrate; and then forming a source-drain metal layer (copper) by magnetron sputtering and plasma-treating a surface of the copper thin film so as to form an uneven granular structure on the surface. This uneven structure increases the adhesion of the photoresist to the surface of the copper thin film during the photoetching, thereby preventing the photoresist from peeling off during the wet-etching of the copper thin film.

The method for manufacturing the array substrate comprises: forming the active semiconductor layer, and then forming the source-drain electrode layer. That is, two mask processes are used to form the active semiconductor layer and the source-drain layer. Alternatively, a half tone or gray tone process may be used, that is, the active semiconductor layer and the source-drain layer are formed by one mask process. The mask process may also be applied to the manufacturing of the gate electrode (copper).

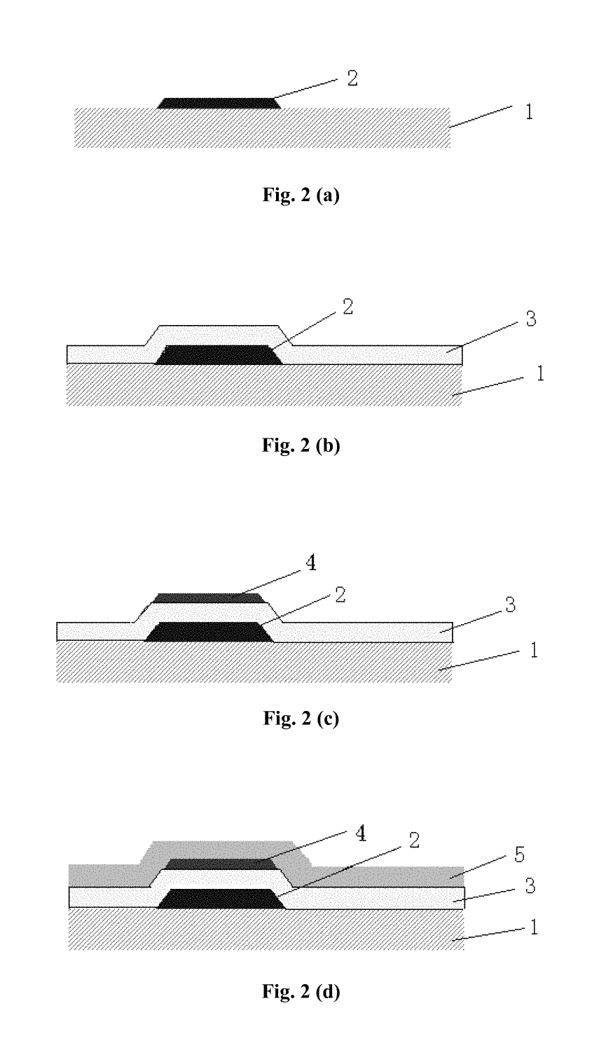

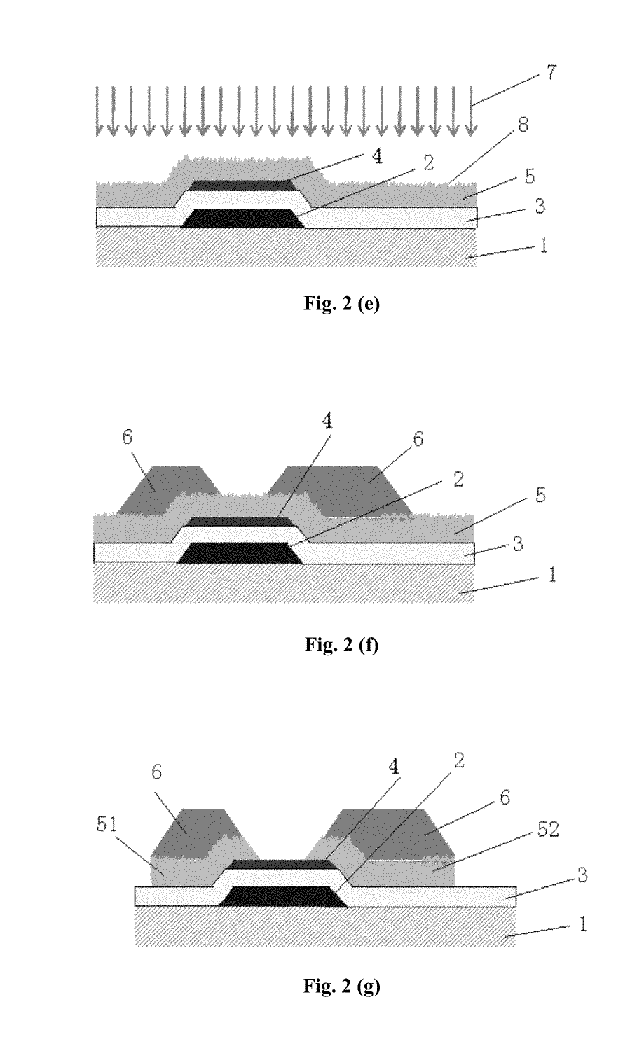

As shown in FIGS. 2(a), 2(b) and 2(c), a gate electrode layer 2, a gate insulating layer (GI) layer 3 and an active semiconductor layer 4 are formed on a base substrate 1 in order. The gate electrode layer may be made of one of copper (Cu), titanium (Ti), molybdenum (Mo), aluminum (Al), tungsten (W) and chromium (Cr), or alloy thereof. The gate insulating layer may be made of one or more selected from TiO₂, Yi₂O₃, Al₂O₃, SiNx, SiON and SiO₂. The active layer may be made of a-Si or oxide semiconductor. For example, the oxide semiconductor may be IGZO, IZO, IGO, GZO, ZnO, ITZO, etc.

As shown in FIG. 2(d), a source-drain metal layer 5 is forming by using a magnetic control method, i.e., a copper thin film is provided on both the active semiconductor layer 4 and the gate insulating layer 3.

Then, referring to FIG. 2(e), a surface of the source-drain metal layer 5 is plasma-treated using one or more halogen-containing gases selected from chlorine Cl₂, Br₂, I₂, HCl, HBr and HI, and the surface of the source-drain metal layer 5 becomes an uneven granular structure or exhibits a rough morphology, wherein the granule structure is a solid CuCl granule structure 8.

In the manufacturing method of the embodiment according to the present disclosure, a base (a table for carrying products made in the process of manufacturing the array substrate) is required to have a temperature lower than 200 degrees Celsius. That is to say, the temperature of the surface of the source-drain metal layer 5 should not be higher than 200 degrees Celsius because copper halide such as CuCl tends to be gasified in a chamber at 200 degrees Celsius or higher and extracted from the chamber.

The solid CuCl is formed as follows:

Cu(s)+xCl→CuClₓ(s)

wherein s represents a solid state and Cu (s) indicates that the copper is solid copper, x represents an integer larger than zero, for example, 1, 2 or the like.

Referring to FIG. 2(f), a photoresist 6 is provided on the surface of the source-drain metal layer 5 where solid CuCl granule structure has been formed.

Then, a photoetching process is carried out, which is followed by wet-etching of the source-drain copper layer. Since solid CuCl granule structure 8 exhibiting granular rough morphology are formed on the surface of the source-drain metal layer 5, the adhesion of the source-drain metal layer 5 to the photoresist is greatly increased during the wet-etching process, which prevents the photoresist from peeling off. As a result, a source electrode 51 and a drain electrode 52 are successfully obtained, as shown in FIG. 2(g).

To sum up, in the embodiments of the present disclosure, the surface of the copper thin film is treated with the plasma containing a halogen element (such as chlorine, bromine, iodine, etc.) to become the uneven granular or rough surface structure. Therefore, during the wet-etching of the copper layer to form the source electrode and the drain electrode for example, the adhesion of the photoresist to its surface is increased and the metal structures such as the source electrode and the drain electrode are successfully formed, thereby leading to increased yield of the array substrate. In addition, the manufacturing method is simple and the cost is low.

It is evident that a person skilled in the art may make modifications or variations to the present disclosure without departing from the spirit and scope of the present disclosure. If these modifications and variations fall within the scope of the claims of the present disclosure and equivalents thereof, the present disclosure is intended to encompass them.

What is claimed is:

1. A method for manufacturing an array substrate, comprising:
forming a first metal layer;
forming an uneven structure on a surface of the first metal layer;
providing a photoresist on the surface of the first metal layer where the uneven structure has been formed; and
exposing and developing the photoresist and etching the first metal layer so as to form a first metal pattern.

2. The method according to claim 1, wherein the first metal layer is a source-drain metal layer and the first metal pattern comprises a source-drain electrode pattern.

3. The method according to claim 2, wherein prior to forming the first metal layer, the method further comprises:
forming a gate electrode on a base substrate;
forming a gate insulating layer on the gate electrode; and
forming an active semiconductor layer on the gate insulating layer, wherein the first metal layer is formed on the active semiconductor layer.

4. The method according to claim 1, wherein forming the uneven structure on the surface of the first metal layer is performed by subjecting the surface of the first metal layer to plasma treatment.

5. The method according to claim 4, wherein the plasma treatment on the surface of the first metal layer is performed by using a halogen-containing gas.

6. The method according to claim 5, wherein the first metal layer is made of copper.

7. The method according to claim 5, wherein the halogen-containing gas is a gas containing one or more of Cl₂, Br₂, I₂, HCl, HBr and HI.

8. The method according to claim 4, wherein the plasma treatment on the surface of the first metal layer is performed at a temperature lower than 200 degrees Celsius so as to form the uneven structure on the surface of the first metal layer.

9. The method according to claim 1, wherein the etching is a wet-etching process.

10. An array substrate, comprising a base substrate, a gate electrode, a gate insulating layer, an active semiconductor layer and a layer of a first metal pattern, wherein an uneven structure is formed on a surface of the layer of the first metal pattern.

11. The array substrate according to claim 10, wherein the uneven structure is a granular structure.

12. The array substrate according to claim 10, wherein the uneven structure is made of a metal halide.

13. The array substrate according to claim 10, wherein the first metal pattern comprises a source electrode pattern, a drain electrode pattern or a source-drain electrode pattern.

14. A display panel, comprising the array substrate according to claim 10.

15. The display panel according to claim 14, wherein the uneven structure is a granular structure.

16. The display panel according to claim 14, wherein the uneven structure on the surface of the layer of the first metal pattern is made of a metal halide.

17. The display panel according to claim 14, wherein the first metal pattern comprises a source electrode pattern, a drain electrode pattern or a source-drain electrode pattern.

18. A display device, comprising the display panel according to claim 14.

19. The display device according to claim 18, wherein the uneven structure is a granular structure.

20. The display device according to claim 18, wherein the uneven structure on the surface of the layer of the first metal pattern is made of a metal halide.
